(19) United States
(12) Patent Application Publication
(10) Pub. No.: US 2025/0113583 A1
(43) Pub. Date: Apr. 3, 2025

(54) Power Semiconductor Device and Method of Producing a Power Semiconductor Device

(71) Applicant: Infineon Technologies AG, Neubiberg (DE)

(72) Inventors: Hans-Jürgen Thees, Dresden (DE); Anton Mauder, Kolbermoor (DE)

(21) Appl. No.: 18/897,067

(22) Filed: Sep. 26, 2024

(30) Foreign Application Priority Data
Sep. 29, 2023 (DE) 102023209628.5

(51) Int. Cl. H01L 29/417; H01L 21/283; H01L 21/311; H01L 29/06; H01L 29/16; H01L 29/66; H01L 29/739; H01L 29/78

(52) U.S. Cl. CPC H10D 64/258; H01L 21/283; H01L 21/311; H10D 12/038; H10D 30/0293; H10D 62/116; H10D 12/481; H10D 30/668; H10D 62/8325

(57) ABSTRACT

A power semiconductor device includes: a semiconductor body with a vertically protruding fin configured to conduct a portion of a nominal load current of the device; and a first load terminal in contact with an upper portion of the fin. An electrode material is arranged adjacent to the fin and electrically insulated from the fin by insulation material. The electrode material is electrically insulated from the first load terminal by an insulating material. The power semiconductor device further includes, on top of the electrode material, insulating sidewall spacers adjacent to the insulating material and the insulation material. The sidewall spacers terminate at a pull-back distance below the top of the fin. The pull-back distance amounts to at least 90% of a width of the fin at the top of the fin.

### TECHNICAL FIELD

This specification refers to embodiments of a power semiconductor device and to embodiments of a method of producing a power semiconductor device.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a blocking state.

Furthermore, some devices provide for reverse load current capability; i.e., the active region of the semiconductor body is further configured to conduct a reverse load current along a reverse load current path between the two load terminals of the device. For example, the RC (Reverse Current) IGBT is one representative of such devices. In an RC IGBT, a single chip unites an IGBT structure and a diode structure.

Irrespective of whether or not the device exhibits an RC configuration, it is generally an aim to design a power semiconductor device with high reliability and high efficiency. For example, in case of controllable devices, reliability may be reduced due to the risk of a breakdown because of an accidental electrical contact between one of the load terminals and the gate electrodes. These accidental contacts can occur due to a processing error during production of the device and/or due to device degradation over time. Even for device configurations with comparably small structures, such accidental contacts must be avoided to ensure a high device reliability.

### SUMMARY

According to an embodiment, a method of producing a power semiconductor device comprises the following steps:
providing a semiconductor body with a vertically protruding fin covered by an insulation material covered by an electrode material, wherein an insulating material covers the electrode material at least partially;
exposing a portion of the electrode material arranged above an upper portion of the fin;
removing the exposed portion of the electrode material to expose the upper portion of the fin covered by the insulation material, thereby forming a respective recess adjacent to both sides of the exposed upper portion of the fin, said recesses being spatially confined by a) the insulation material, b) the electrode material and c) the insulating material;
forming, in the recesses and on top of the electrode material, insulating sidewall spacers adjacent to the insulating material and the insulation material, wherein the sidewall spacers terminate at a pull-back distance below the top of the fin, wherein the pull-back distance amounts to at least 90% of the width of the fin at the top of the fin;
forming an interlayer dielectric, ILD, on top of the exposed portions of the device by a) providing a further insulation material and b) a subsequent removal processing step to re-expose both the upper portions of the sidewall spacers and the upper portion of the fin by removing a portion of the insulating material covering the fin;
forming a first load terminal, said first load terminal being configured to contact the upper portion of the fin.

According to a further embodiment, a power semiconductor device comprises: a semiconductor body with a vertically protruding fin configured to conduct a portion of the device's nominal load current; a first load terminal in contact with an upper portion of the fin. The electrode material is arranged adjacent to the fin and electrically insulated from the fin based on insulation material. The electrode material is electrically insulated from the first load terminal based on an insulating material. The power semiconductor device further comprises, on top of the electrode material, insulating sidewall spacers adjacent to the insulating material and the insulation material, wherein the sidewall spacers terminate at a pull-back distance below the top of the fin, wherein the pull-back distance amounts to at least 90% of the width of the fin at the top of the fin.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIGS. 1A-B both schematically and exemplarily illustrate a respective section of a vertical cross-section of a power semiconductor device in accordance with one or more embodiments;

FIGS. 2A-B both schematically and exemplarily illustrate a respective section of a vertical cross-section of a power semiconductor device in accordance with one or more embodiments;

FIG. 3 schematically and exemplarily illustrates a section of a vertical cross-section of a power semiconductor device;

FIG. 4 schematically and exemplarily illustrates a section of a vertical cross-section of a power semiconductor device in accordance with one or more embodiments; and

FIGS. 5-13 schematically and exemplarily illustrate, based on several sections of a vertical cross-section of a device being processed, a method of producing a power semiconductor device in accordance with some embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device that may be used within a power converter or a power supply. Thus, in an embodiment, such power semiconductor device can be configured to carry a load current that is to be fed to a load and/or, respectively, that is provided by a power source. For example, the power semiconductor device may comprise one or more active power semiconductor unit cells, such as a monolithically integrated diode cell, a derivative of a monolithically integrated diode cell, a monolithically integrated transistor cell, e.g., a monolithically integrated IGBT or MOSFET cell and/or derivatives thereof. Such diode/transistor cells may be integrated within a single chip. A plurality of such cells may constitute a cell field that is arranged within an active region of the power semiconductor device.

The term “blocking state” of the power semiconductor device may refer to conditions, when the power semiconductor device is in a state configured for blocking a load current flow while an external voltage is applied. More particularly, the power semiconductor device may be configured for blocking a forward load current through the power semiconductor device while a forward voltage bias is applied. In comparison, the power semiconductor device may be configured for conducting the forward load current in a “conducting state” of the power semiconductor device while a forward voltage bias is applied. A transition between the blocking state and the conducting state may be controlled by a control electrode or, more particularly, an electrical potential of the control electrode. Said electrical characteristics may, of course, only apply within a predetermined working range of the external voltage and the current density within the power semiconductor device. The term “blocking state” therefore may refer to conditions with the power semiconductor device being in the blocking state while a forward voltage bias is applied.

The term “power semiconductor device” as used in this specification intends to describe a power semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above, e.g., up to at least 500 V or even more, e.g., up to at least 3 kV, or even up to 10 kV or more, depending on the respective application.

For example, the term “power semiconductor device” as used in this specification is not directed to logic semiconductor devices that are used for, e.g., storing data, computing data and/or other types of semiconductor based data processing.

For example, the power semiconductor device described below may be a single semiconductor chip, e.g., exhibiting a stripe cell configuration (or a cellular/needle cell configuration) and can be configured to be employed as a power component in a low-, medium- and/or high voltage application.

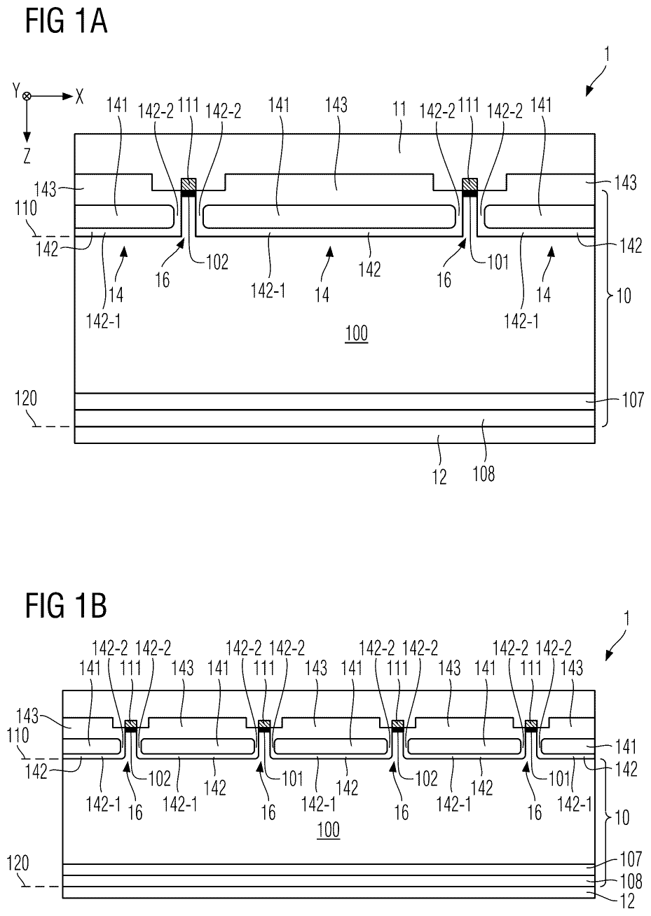

FIGS. 1A-B both schematically and exemplarily illustrate a respective section of a vertical cross-section of a power semiconductor device 1 in accordance with one or more embodiments. According to these embodiments, the power semiconductor device 1 exhibits an IGBT configuration.

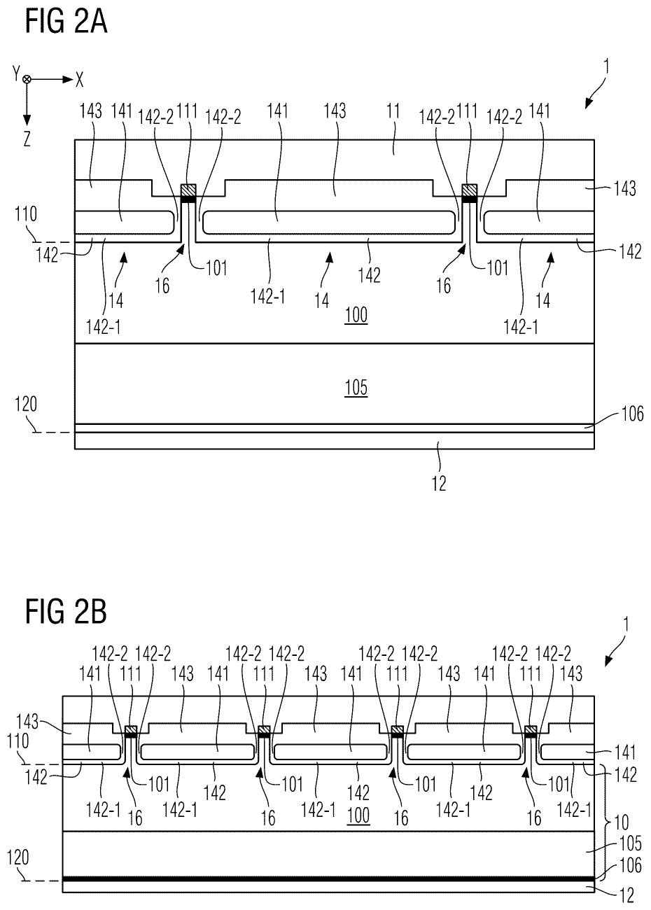

FIGS. 2A-B both schematically and exemplarily illustrate a respective section of a vertical cross-section of a power semiconductor device 1 in accordance with one or more other embodiments. According to these embodiments, the power semiconductor device 1 exhibits a MOSFET configuration.

The following description refers to each of FIG. 1A to FIG. 2B.

The power semiconductor device 1, herein also referred to as “device”, comprises, in a single chip, a semiconductor body 10 configured to conduct a load current between a first load terminal 11 at a first side 110 of the semiconductor body 10 and a second load terminal 12 at a second side 120 of the semiconductor body 10.

The first side 110 and the second side 120 may be arranged opposite of each other. E.g., the first side 110 is a front side of the device 1 and the second side 120 is a back side of the device 1. Accordingly, the device 1 may exhibit a vertical configuration according to which the load current within the device 1 follows a path in parallel to the vertical direction Z.

The device 1 further comprises a drift region 100 of a first conductivity type within the semiconductor body 10. Herein, the term “drift region” is employed with the meaning the skilled person typically associates therewith in the field of power semiconductor devices. For example, the vertical extension of the drift region 100 influences the voltage blocking capabilities of the device 1.

The device 1 further comprises fins 16 protruding from the first side 110 against the vertical direction Z. At least some of the fins 16 may be associated with respective control electrodes 141. Upon subjecting the control electrodes with a corresponding control signal, the device 1 may be set into the blocking state or into the conductive state. For example, to this end, the control electrodes 141 may be configured to induce or, respectively, cut-off conductive channels in the fins 16.

The control electrodes 141 are electrically isolated, at least based on an insulation structure 142, 143, from both the first load terminal 11 (and the second load terminal 12) and from the semiconductor body 10. The insulation structure 142 comprises a bottom insulating layer 142-1 electrically insulating the control electrode 141 from the semiconductor body and a gate insulating layer 142-2 electrically insulating the control electrode 141 from the fin 16. The gate insulating layer 142-2 may also be referred to as gate dielectric (layer).

The fins 16 are electrically connected with the first load terminal 11, e.g., based on contacts 111, as illustrated in FIGS. 1A-2B. These contacts 111 will be described in greater detail below. In a region where the fin 16 adjoins the contact 111, the fin may comprise a first doped region 101 of the first conductivity type or a second doped region 102 of the second conductivity type. In case of the IGBT configuration (cf. FIGS. 1A-B), both types (first doped region 101 of the first conductivity type and second doped region 102 of the second conductivity type) are realized; thereby, the device 1 exhibits a bipolar configuration. The ration between fins 16 of the first conductivity type (fins 16 comprising a first doped region 101) and fins 16 of the second conductivity type (fins 16 comprising a second doped region 102) may be at least 1 to 1, at least 1 to 3, or even at least 1 to 6. In other words, for every fin 16 comprising one of the first doped regions 101 there may be at least 1, at least 3, or even at least 6 fins 16 comprising one of the second doped regions 102. In case of the MOSFET configuration (cf. FIGS. 2A-B), the fins 16 are only provided with the first doped regions 101 of the first conductivity type; thereby, the device 1 exhibits a unipolar configuration. Alternatively, it is possible also in case of a MOSFET configuration, that the device 1 comprises fins 16 of the first conductivity type (fins 16 comprising a first doped region 101) and fins 16 of the second conductivity type (fins 16 comprising a second doped region 102).

Furthermore, the device 1 may comprise a shield region of the second conductivity type buried in the semiconductor body 10 and spaced apart from the front side 110. Said shield region may be directly connected to the first load terminal 11 or be connected to the first load terminal 11 via one or more of the fins 16 of the second conductivity type (fins 16 comprising a second doped region 102). Two or more of said shield regions may form a JFET together.

Each of the fins 16 may be connected in parallel between the first load terminal 11 and the second load terminal 12, wherein each of the fins 16 can be configured to conduct a part of the load current between the first load terminal 11 and the second load terminal 12.

The drift region 100 is arranged below the fins 16; in other words, the drift region 100 is arranged below the front side 110 of the semiconductor body 10, whereas the fins 16 are arranged above the front side 110, in accordance with an embodiment. At the front side 110, the fins may adjoin the drift region 100 or another doped region below the front side 110 of the semiconductor body 10.

Due to the protruding fins 16 (e.g., characterized by their width being smaller than a lithography resolution used for forming them), the device 1 (in both the MOSFET and the IGBT configuration) may also be referred to as “FinFET controlled power transistor” due to the cell head that comprises “FinFET structures”. However, also the device 1 as a whole may be called “FinFET”. For example, the fins 16 may be characterized by a width being smaller than 100 nm.

The semiconductor body 10 at the back side 120 may be designed accordingly: In case of the IGBT configuration (cf. FIGS. 1A-B), the drift region 100 may adjoin a field stop region 107 of the first conductivity type, which may adjoin an emitter region 108 of the second conductivity type arranged in electrical connection with the second load terminal 12. The field stop region 107 of the first conductivity type exhibits a greater dopant concentration than the drift region 100, but typically a smaller total extension along the vertical direction Z as compared to the drift region 100, as illustrated. In case of the IGBT configuration (cf. FIGS. 1A-B), the drift region 100 may adjoin a buffer region 105 of the first conductivity type, which may adjoin a contact region 106 of the first conductivity type arranged in electrical connection with the second load terminal 12. The buffer region 105 of the first conductivity type exhibits a greater dopant concentration than the drift region 100, but typically a smaller total extension along the vertical direction Z as compared to the drift region 100, as illustrated. Furthermore, the contact region 106 of the first conductivity type exhibits a greater dopant concentration than the buffer region 105, but typically a smaller total extension along the vertical direction Z as compared to the buffer region 105, as illustrated.

The present disclosure in relates to the configuration of the fins 16 and corresponding processing techniques, and in particular to the region where the fins 16 adjoin the first load terminal 11.

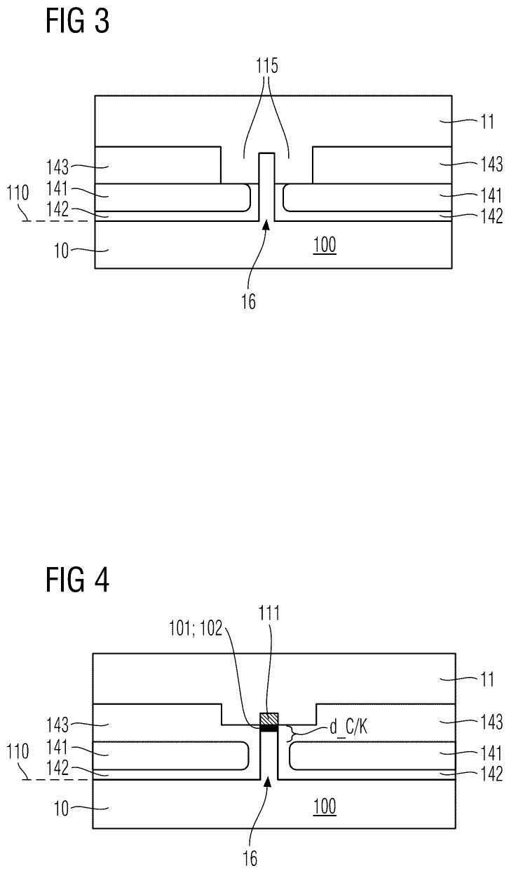

For example, referring to FIG. 3, a vertical FinFET pattern can be contacted by a contact hole 110 which is wider than the actual fin 16 in order to avoid issues with lateral misalignment and variations of the dimensions of the pattern of the contact hole etch. Due to vertical tolerances in the contact hole etch, the bottom of the contact hole 110 may reach the control electrode 141 thus producing an electrical short with the first load terminal 11. Even in case of no short, the depth variation of the contact hole 110 can lead to larger device scattering, variation of the contact properties, or varying electrical properties.

For example, referring to FIG. 4, in case the top of the fin 16 which is embedded in the metal of the first load terminal 11 is fully silicided during formation of the contact 111, the actual contact interface will be the bottom of the silicided area/the contact 111. Thus, any scattering of the vertical distance d_C/K between the bottom of the silicided area/the contact 111 and the upper end of the first (or second) doped region 101 (or 102) may lead to scattering of the device performance.

To address the challenges described with respect to FIGS. 3 and 4, embodiments of a device production method are proposed herein. The devices 1 described above with respect to FIGS. 1A-2D may be produced according to one or more of the embodiments of the method described below with respect to FIGS. 5 to 13.

For example, cf. FIG. 5, in a first step 200 of an embodiment of the method, a semiconductor body 10 is provided with a vertically protruding fin 16 covered by an insulation material 142 covered by an electrode material 141, wherein an insulating material 143 covers the electrode material 141 at least partially. For example, a starting point may hence be the preparation of the control electrode 141, e.g., using thin gate layers as illustrated in FIG. 5. The insulating material 143 (e.g., based on SiO₂) may form a mask layer which may formed with an upper edge which is at the same level as the top of the gate layer. This may, e.g., be accomplished by using a thicker deposition and employing a subsequent chemical-mechanical polishing, CMP, processing step.

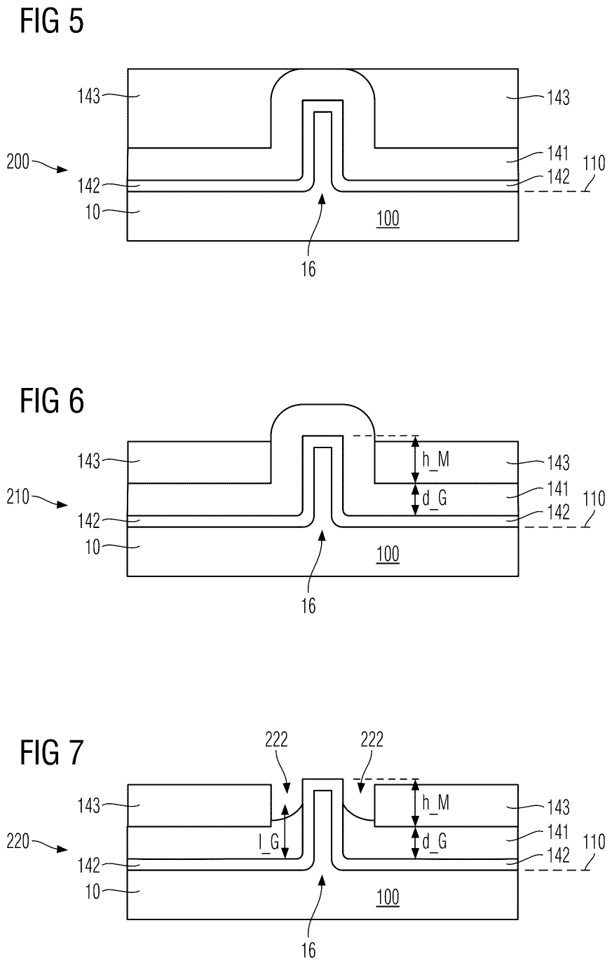

Subsequently, cf. FIG. 6, a portion of the electrode material 141 arranged above an upper portion of the fin 16 is exposed (step 210). For example, said mask layer is accordingly recessed to a level below the lower end of the gate layer on top of the fin 16, as indicated by the dashed line in FIG. 6. After step 210, both the control electrode 141 and the mask layer/insulating material 143 may exhibit defined thicknesses h_M and d_G, respectively.

Subsequently, a step 220 of removing (cf. FIG. 7) the exposed portion of the electrode material 141 may be carried out to expose the upper portion of the fin 16 covered by the insulation material 142, thereby forming a respective recess 222 adjacent to both sides of the exposed upper portion of the fin 16, said recesses 222 being spatially confined by a) the insulation material 142, b) the electrode material 141 and c) the insulating material 143. For example, the gate layer (electrode material 141) is recessed using isotropic etching in order to reach a desired channel length l_G. The etching time may depend on the initial thickness h_M of the mask layer (insulating material 143), since the etching may be isotropic. However, also a combination of isotropic and anisotropic etch processes may be applied as long as they are highly selective to the chosen materials 142 and 143.

Accordingly, the electrode material removal step 220 may define said channel length l_G in the fin 16, in accordance with an embodiment. Also, the electrode material removal step 220 can be based on an isotropic etch processing step. The etch processing step may be either an isotropic etch processing step, an anisotropic etch processing step, or a combination thereof.

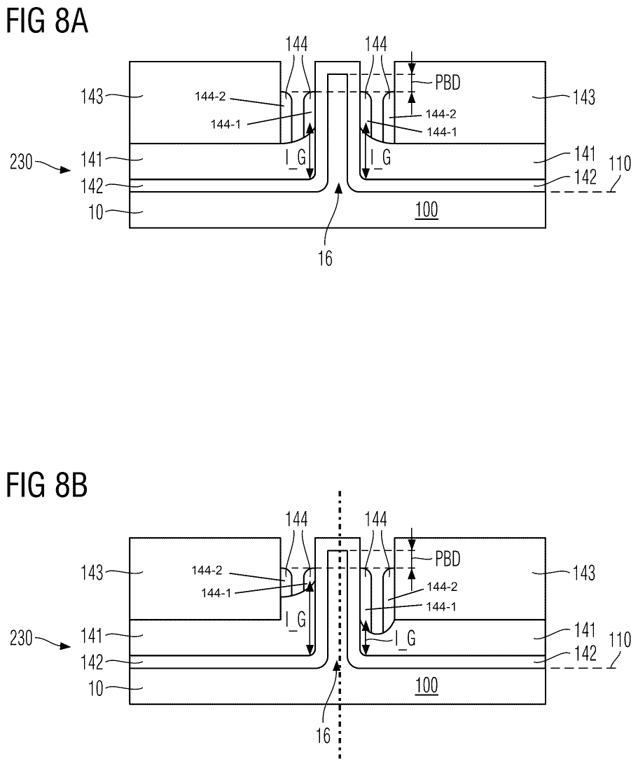

Then, in step 230, cf. FIGS. 8A and 8B, insulating sidewall spacers 144 adjacent to the insulating material 143 and the insulation material (142) are formed in the recesses 222 and on top of the electrode material 141, wherein the sidewall spacers 144 terminate at a pull-back distance PBD below the top of the fin 16, wherein the pull-back distance PBD may, for example, be at least 15 nm and at most 100 nm at the top of the fin 16. During step 230, the insulation material 142 may remain substantially intact. For example, step 230 may be a selective etching process removing the spacer 144 selectively to the insulation material 142. As shown in FIG. 8B, the preceding step 220 of removing portions of the electrode material 141 can be carried out independently from the channel length l_G. In FIG. 8B two different examples for the channel length l_G are shown. It hast to be noted, that on both sides of the vertical dotted line two different embodiments of the device 1 are depicted. The channel length l_G of the embodiment on the left side is different to the channel length l_G of the embodiment on the right side. FIG. 8B shows that the proposed method works independently from the desired channel length l_G.

A stable process for a defined exposed fin height h_F of the fin 16 over the insulating material 142 is a prerequisite for stable contact properties when the contact of the first doped regions 101 or second doped regions 102 to the first load terminal 11 is formed later. Therefore the process variations regarding the exposed fin height h_F have to be kept low. The variation of isolation thickness Dd needs to be accounted for by proper device design measures of the device 1.

For example, in step 230, to produce the sidewall spacers 144, an insulator (e.g., Si₃N₄) is conformally deposited which can be selectively etched to the insulating material 143 and the control electrode dielectric 142 (insulating material 142). In a next processing step, an anisotropic etch step for the insulator (e.g., Si₃N₄) is performed. By selecting the thickness of the layer and the etching time, the sidewall spacers 144 with the defined pull-back distance PBD from the top of the fin 16 or the upper part of the control electrode dielectric 142, respectively, can be formed. For example, with the availability of a sufficient conformal deposition (e.g., using LPCVD (low pressure chemical vapour deposition), PEALD (plasma-enhanced atomic layer deposition) Si3N4 processes) at a thickness larger than half the thickness of the electrode material 141 (i.e., said gate layer), the illustrated gap between the two sidewall spacers on both sides of the fin 16 may be closed. For less conformal layers (e.g., based on a PECVD (plasma-enhanced chemical vapor deposition) process) or layers with a weak gap fill capabilities the maximum spacer width may be limited as shown in FIGS. 8A and 8B. The pull-back distance PBD of the inner sidewall spacers 144-1 (adjacent to the fin 16) and the outer sidewall spacers 144-2 (adjacent to the insulating material 143) may differ depending on the relative height of the insulating material 143 to the insulating material 142 above the fins 16. Electrically relevant for the device 1 is mostly the pull-back distance PBD of the inner sidewall spacers 144-1.

The sidewall spacer forming step 230 may include a deposition processing step and a subsequent anisotropic etch processing step, in accordance with an embodiment. The duration of said anisotropic etch processing step determines the pull-back distance PBD. Furthermore, the deposition processing step can be an at least substantially conformal deposition processing step.

Even though not clearly shown in FIGS. 1A-2B, said insulting sidewall spacers 144 may also be present in the structures of FIGS. 1A-2B.

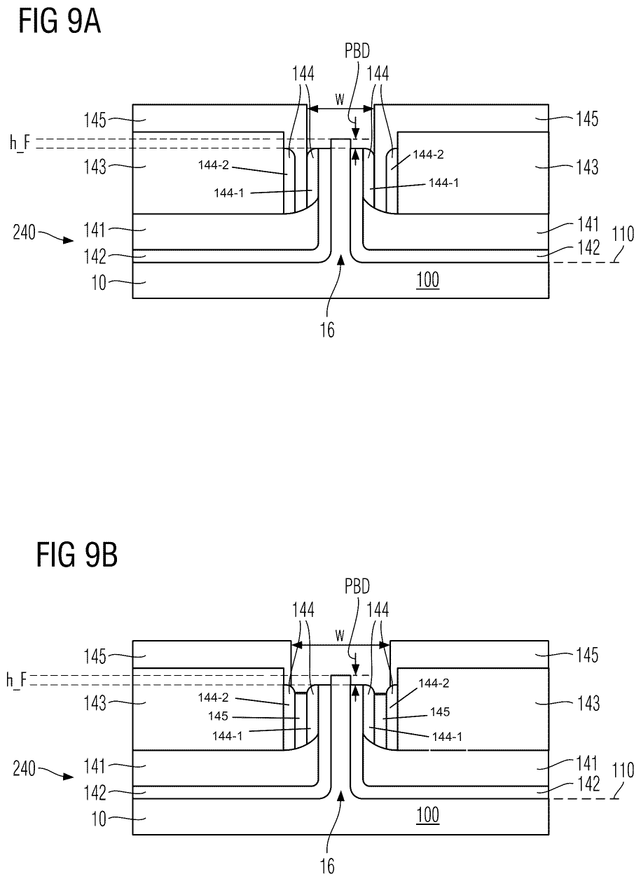

Referring to FIGS. 9A and 9B, in a subsequent step 240, an interlayer dielectric, ILD, is formed on top of the exposed portions of the device 1 by a) providing a further insulation material 145 and b) a subsequent removal processing step to re-expose both the upper portions of the sidewall spacers 144 and the upper portion of the fin 16 by removing a portion of the insulating material 142 covering the fin 16. As illustrated in FIGS. 9A and 9B, the width w may be chosen to place the contact hole edges at the lateral position of the inner sidewall spacers 144-1 (adjacent to the fin 16) or the outer sidewall spacers 144-2 (adjacent to the insulating material 143) . . . . A resulting height h_F of the portion of fin 16 protruding over the insulating material 142 may be at least 15 nm and at most 100 nm. The typical value may be around 50 nm. The ILD 145 can be based on SiO₂, for example. For example, first, SiO₂ to form the ILD 145 is deposited and then the contact hole etch selective to the spacer material 144 can be performed to re-expose upper portions of the fin 16 and of the adjacent sidewall spacers 144. When the etch front reaches the sidewall spacer's 144 upper edge, an end point can be detected and the etching process can be stopped. Thereby, the overlap of the contact hole and the fin 16 is defined by the sidewall spacer 144.

In the embodiment as depicted in FIG. 9A, the width w of the contact hole can for example be defined as smaller (by a safety margin) than the width of the fin 16 plus two times the control electrode dielectric thickness (insulating material) 142, 142-2 adjacent to the fin 16 and two times the thickness of the inner the sidewall spacers 144-1. In providing the safety margin, there even can be provided a process window for the lateral alignment and width variation of the contact hole mask on the fin 16.

In the embodiment as depicted in FIG. 9B, the width w of the contact hole can for example be defined as smaller (by a safety margin) than the width of the fin 16 plus two times the control electrode dielectric thickness (insulating material) 142, 142-2 adjacent to the fin 16 plus two times the thickness of the control electrode 141. In providing the safety margin, there even can be provided a process window for the lateral alignment and width variation of the contact hole mask on the fin 16.

In another embodiment (not depicted), the width w of the contact hole can be defined even larger compared to FIG. 9B. In this case, reaching the spacer pattern 144 may deliver the endpoint signal during the etching process of the contact hole. As in the other embodiments (as depicted in FIGS. 9A and 9A), the depth of the contact hole and the overlap with the fin 16 is defined by the spacer pullback PBD.

Accordingly, in an embodiment, the sub-step a) of the ILD forming step 240 may include a deposition processing step to cover the recesses 222, the upper portion of the fin 16 and the insulating material 143 with the further insulation material 145. Sub-step b) of the ILD forming step 240 can be based on an etch processing step. As described above, the etch processing step may include detecting that an etch front reaches the sidewall spacers 144, in particular the upper edges thereof.

In addition, as illustrated, the ILD forming step 240 may lead to a contact hole, wherein the fin 16 protrudes from a bottom portion of the contact hole, cf. FIGS. 9A-B. The contact hole may exhibit a width w of less than the sum of the width of the fin 16, twice the width of the insulating material 142 between the fin 16 and the electrode material 141 and twice the width of one of the sidewall spacers 144 adjacent to the fin 16.

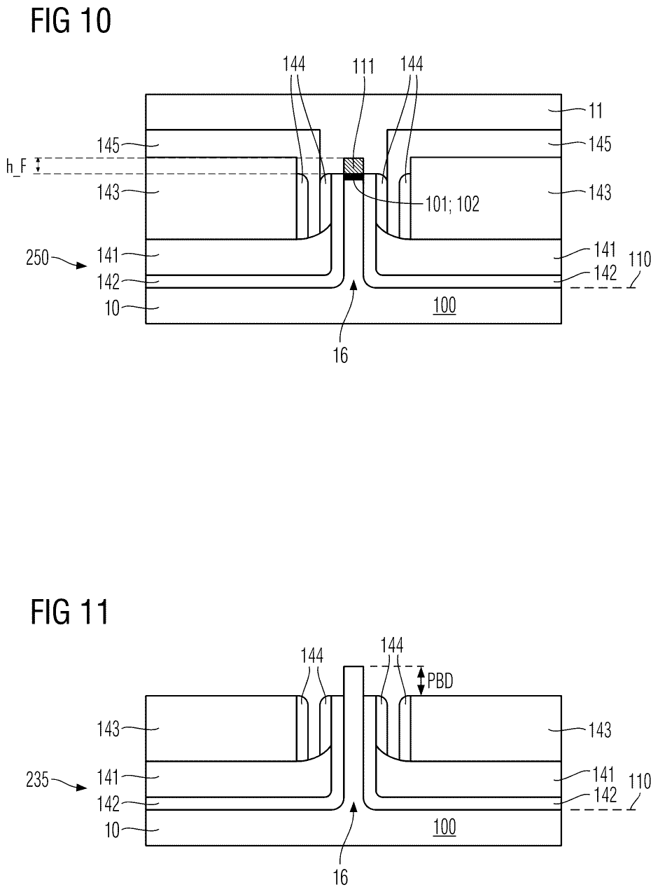

Referring to FIG. 10, in a next step 250, the first load terminal 11 is formed, e.g., above the ILD 145, wherein said first load terminal 11 is configured to contact the upper portion of the fin 16. Before formation of the first load terminal 11, the upper portion of the fin 16 may be subjected to at least one silicide formation processing step to form the contact 111. In addition, the first doped regions 101 and/or the second doped regions 102 may be formed in the fins 16 before formation of the first load terminal 11, e.g., by carrying out a contact implantation processing step on the upper portion of the fins 16.

Another embodiment of the method is illustrated in FIGS. 11-13. FIG. 11 illustrates the processing stage similar to FIGS. 8A-B. According to FIG. 11, the sidewall spacers 144 have been formed and the ILD 143 has been removed down to a level corresponding to the top ends of the sidewall spacers 144; i.e., both the ILD 143 and the sidewall spacers 144 terminate at the same vertical level. For example, in accordance with the embodiments corresponding to FIGS. 11-13, the material of the sidewall spacers 144 may be selected for better homogeneity in order to allow for thicker sidewall spacers 144 and allow larger process windows for overlay tolerances of the contact hole lithography to the fins 16. For example, a very conformal oxide film, like TEOS (tetraethoxysilane), is selected as material for the sidewall spacers 144. Since in anisotropic etch processes even low-densified PECVD-TEOS will be etched at the same etching rate as other masking oxides or a pure SiO₂ gate oxide, there will be a very homogeneous pull-back of the device surface (as illustrated in FIG. 10). Also, subsequent ALD (atomic layer deposition) processes can be used to deposit the oxide films with high precision.

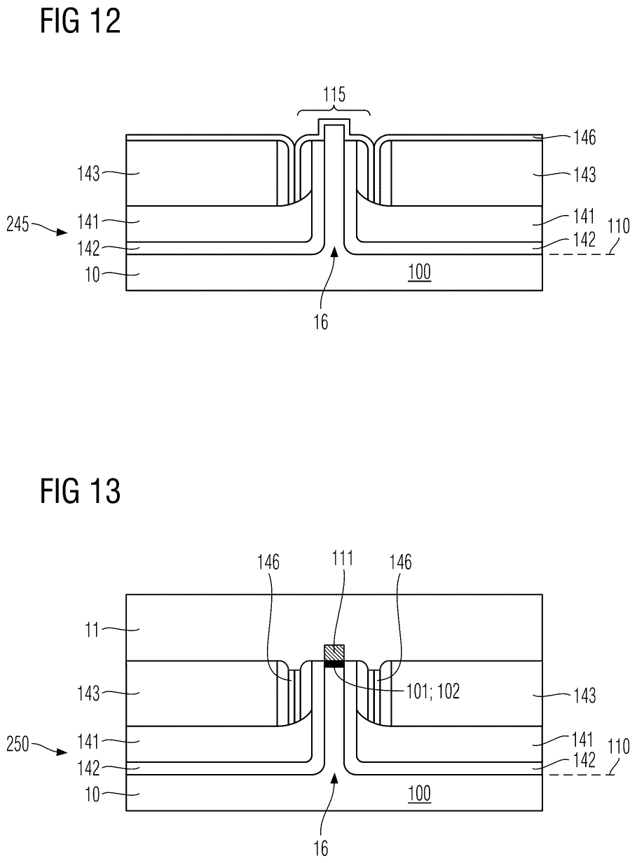

Referring to FIG. 12, in step 245, a liner 146, e.g., based on Si3N4, is deposited. The liner 146 can be etched selectively to SiO₂. The thickness of the liner can be selected so that a gap between the sidewall spacers 144 can be covered. An eventually remaining small void (not illustrated) is of minor importance, since there (i.e., in the gap between the adjacent sidewall spacers 144) no high electric field strengths occur.

Afterwards, cf. step 250 in FIG. 13, the first load terminal 11 may be formed, as described above with respect to FIG. 10. Again, before formation of the first load terminal 11, the upper portion of the fin 16 may be subjected to at least one silicide formation processing step to form the contact 111. In addition, the first doped regions 101 and/or the second doped regions 102 may be formed in the fins 16 before formation of the first load terminal 11, e.g., by carrying out a contact implantation processing step on the upper portion of the fins 16.

In case, only the fins 16 must be contacted, a lithography process may be performed only to open the etch stop area in the region 115 designated in FIG. 12. In this case, topology in the contact hole is low and a simple metal stack can be used (e.g., AlSiCu or AlCu above a TiSi/TiN barrier). In case of another interlayer dielectric is needed for other purposes, this layer can be opened using standard contact hole etching with etch stop on the liner plus subsequent break-through step through the liner.

Wet chemical cleaning can have high etching rates on undensified or weakly densified sidewall spacers. For improving resistance against defects caused by etching out the sidewall spacers 144 in the embodiment according to FIGS. 10 and 11, before depositing the (e.g., SiO₂ based) sidewall spacers of FIG. 10, an optional thin nitride liner can be deposited (not shown in the figures). Since it is intended merely as redundancy layer, it can remain thin and thus uncritical with respect to non-conformal deposition processing steps.

Presented herein is also a power semiconductor device 1 that has been produced in accordance with one of the exemplary methods described above. I.c., as indicated above, the devices illustrated in FIGS. 1A to 2B may be equipped with said sidewall spacers 144.

For example, the power semiconductor device 1 according to the present disclosure comprises: a semiconductor body 10 with a vertically protruding fin 16 configured to conduct a portion of the device's nominal load current; a first load terminal 11 in contact with an upper portion of the fin 16. The electrode material 141 is arranged adjacent to the fin 16 and electrically insulated from the fin 16 based on insulation material 142. The electrode material 141 is electrically insulated from the first load terminal 11 based on an insulating material 143. The power semiconductor device further comprises: on top of the electrode material 141, insulating sidewall spacers 144 adjacent to the insulating material 143 and the insulation material 142, wherein the sidewall spacers 144 terminate at a pull-back distance PBD below the top of the fin 16, wherein the pull-back distance PBD amounts to at least 90% of the width of the fin 16 at the top of the fin 16.

Regarding all embodiments, each of the fins 16 may have a width (along the first lateral direction X) of at least 20 nm, wherein this width may be present at the top of the respective fin 16, and a height (along the vertical direction Z) of at least 0.25 μm. Further, each of the fins 16 may have a width of at most 100 nm and a height of at most 1 μm. The width of the fins 16 may be smaller than the lithography resolution being used during manufacture of the device 1.

The height h_F of the portion of fin 16 protruding over the insulating material 142 may be at least 15 nm and at most 100 nm. The typical value may be around 50 nm.

Still regarding all embodiments, it may be provided that at a vertical level where the contact between the first load terminal 11 and the respective fin 16 is established, the lateral area the first load terminal 11 is greater than the lateral areal the fin 16 that is being contacted. This optional feature is, e.g., illustrated, in each of FIGS. 1A-2B, 4, 10 and 13.

Furthermore, the device 1 is for example not intended to be used for logical processes, such as carrying out calculations and/or storage functions, but intended to be used as power semiconductor device in a power application, such as a power converter. To this end, the device's nominal load current may amount to at least 5 A.

In each of the described embodiments, the power semiconductor device 1 can be configured with a forward blocking voltage of at least 500 V.

Furthermore, in each of the described embodiments, the semiconductor body 10 of the power semiconductor device 1 may be based on silicon. In other embodiments, the semiconductor body 10 of the power semiconductor device 1 may be based silicon carbide SiC or another wide bandgap semiconductor material.

In the above, embodiments pertaining to power semiconductor devices and corresponding production methods were explained.

For example, these power semiconductor devices are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1−x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of producing a power semiconductor device, the method comprising:
providing a semiconductor body with a vertically protruding fin covered by an insulation material covered by an electrode material, wherein an insulating material at least partially covers the electrode material;
exposing a portion of the electrode material arranged above an upper portion of the fin;
removing the exposed portion of the electrode material to expose the upper portion of the fin covered by the insulation material, thereby forming a respective recess adjacent to both sides of the exposed upper portion of the fin, the recesses being spatially confined by the insulation material, the electrode material, and the insulating material;
forming, in the recesses and on top of the electrode material, insulating sidewall spacers adjacent to the insulating material and the insulation material, wherein the sidewall spacers terminate at a pull-back distance below the top of the fin, wherein the pull-back distance amounts to at least 90% of a width of the fin at the top of the fin;
forming an interlayer dielectric (ILD) on top of the exposed portions of the power semiconductor device by providing a further insulation material and a subsequent removal processing step to re-expose both the upper portions of the sidewall spacers and the upper portion of the fin by removing a portion of the insulating material covering the fin;
forming a first load terminal configured to contact the upper portion of the fin.

2. The method of claim 1, wherein the providing the further insulation material comprises a deposition processing step to cover the recesses, the upper portion of the fin and the insulating material with the further insulation material.

3. The method of claim 1, wherein the subsequent removal processing step is an etch processing step.

4. The method of claim 3, wherein the etch processing step includes detecting that an etch front reaches the sidewall spacers.

5. The method of claim 1, wherein the forming the ILD leads to a contact hole, and wherein the fin protrudes from a bottom portion of the contact hole.

6. The method of claim 5, wherein the contact hole exhibits a width of less than a sum of the width of the fin, twice a width of the insulating material between the fin and the electrode material, and twice a width of one of the sidewall spacers adjacent to the fin.

7. The method of claim 1, wherein the forming the insulating sidewall spacers comprises a deposition processing step and a subsequent anisotropic etch processing step.

8. The method of claim 7, wherein a duration of the anisotropic etch processing step determines the pull-back distance.

9. The method of claim 7, wherein the deposition processing step is a conformal deposition processing step.

10. The method of claim 1, wherein the removing the exposed portion of the electrode material includes an isotropic etch processing step.

11. The method of claim 1, further comprising:
subjecting the upper portion of the fin to a contact implantation processing step.

12. The method of claim 1, further comprising:
subjecting the upper portion of the fin to at least one silicide formation processing step.

13. The method of claim 1, wherein the fin has a width of at least 20 nm and a height of at least 0.25 μm.

14. A power semiconductor device, comprising:
a semiconductor body with a vertically protruding fin configured to conduct a portion of a nominal load current of the power semiconductor device;
a first load terminal in contact with an upper portion of the fin;
an electrode material arranged adjacent to the fin, wherein the electrode material is electrically insulated from the fin by insulation material and electrically insulated from the first load terminal by an insulating material; and
on top of the electrode material, insulating sidewall spacers adjacent to the insulating material and the insulation material, wherein the sidewall spacers terminate at a pull-back distance below a top of the fin, wherein the pull-back distance amounts to at least 90% of a width of the fin at the top of the fin.

15. The power semiconductor device of claim 14, wherein the nominal load current amounts to a least 5 A.

16. The power semiconductor device of claim 14, wherein the power semiconductor device is configured with a forward blocking voltage of at least 500 V.

17. The power semiconductor device of claim 14, wherein the power semiconductor device (1) has a MOSFET or an IGBT configuration.

18. The power semiconductor device of claim 14, wherein the semiconductor body is based on silicon carbide (SIC).

19. The power semiconductor device of claim 14, wherein the semiconductor body comprises a front side and a back side, wherein the fin protrudes form the front side, and wherein the power semiconductor device further comprises a second load terminal at the back side.

20. The power semiconductor device of claim 19, wherein the semiconductor body further comprises a drift region between the first load terminal and the second load terminal.

21. The power semiconductor device of claim 19, wherein the fin is one of a plurality of fins protruding at the front side, wherein the fins are connected in parallel between the first load terminal and the second load terminal, and wherein each of the fins is configured to conduct part of a load current between the first load terminal and the second load terminal.
